(19) United States
(12) Patent Application Publication
(10) Pub. No.: US 2013/0069218 A1
(43) Pub. Date: Mar. 21, 2013

(54) HIGH DENSITY PACKAGE INTERCONNECT WITH COPPER HEAT SPREADER AND METHOD OF MAKING THE SAME

(71) Applicant: Lee Hua Alvin Seah, Singapore (SG)

(72) Inventor: Lee Hua Alvin Seah, Singapore (SG)

(73) Assignee: STMicroelectronics Asia Pacific Pte Ltd., Singapore (SG)

(21) Appl. No.: 13/237,694

(22) Filed: Sep. 20, 2011

(51) Int. Cl. H01L 23/34; H01L 21/56; H01L 21/52

(52) U.S. Cl. 257/712; 438/118; 257/E23.08; 257/E21.5; 257/E21.502

(57) ABSTRACT

The integrated circuit packaging techniques of the disclosed embodiments utilize a thermally conductive heat sink to partially enclose an integrated circuit. The heat sink is separated from the integrated circuit by a substrate that is conformally positioned into a recess in the heat sink, enabling the heat sink to transfer thermal energy from the integrated circuit.

### BACKGROUND

1. Technical Field

The present disclosure generally relates to cooling integrated circuits.

2. Description of the Related Art

Semiconductor circuits that are subjected to undesirable quantities of heat may operate differently than designed, may malfunction, or may fail. The heat may be generated through power dissipation that occurs during the operation of a semiconductor circuit. As a result, the dissipation and distribution of heat from a semiconductor die can be of great interest to a manufacturer.

Some existing approaches to transferring heat from a semiconductor die include enclosing the semiconductor die in a package. The existing approaches to semiconductor die packaging are, however, limited by the electrical interface between the semiconductor die and the external electrical interface of the package, such as solder balls. For example, as illustrated by U.S. Patent Application Publication No. 2006/0030150, after placing a semiconductor die in a recess of a substrate existing approaches to packaging require forming direct electrical connections to bonding pads on an upper exposed surface of the die. The direct electrical connections to the upper exposed surface of the die require multiple process steps, such as depositing a dielectric layer, selectively etching the dielectric layer, and depositing a conductive layer within portions of the dielectric layer that have been selectively etched away.

Several other popular methods of channeling heat at the package level exist, but many of them consume power in the process. Examples include thermoelectric cooling, integrated micro pumps inside the silicon substrate below the high power region of integrated circuits, and fluid-based cooling of hot regions of integrated circuits.

### BRIEF SUMMARY

The passive thermal energy transfer techniques of the herein disclosed embodiments of the invention utilize integrated circuit packages to improve heat sink-based cooling from a semiconductor die.

According to one embodiment of the invention, a flexible substrate is pressed into a recess of a highly thermally conductive heat sink. The flexible substrate carries traces from a surface within the recess to a surface that is outside of the recess. The use of various configurations of semiconductor dies within the recess is disclosed herein. For example, because an upper surface of a semiconductor die need not be exposed for the disclosed packaging technique, electrically coupling the semiconductor die to the flexible substrate may be performed by either wire bonding or by the use of conductive bumps. Additionally, the flexible substrate provides electrical isolation between the semiconductor die and the high K heat sink, which may be formed from metal such as copper, aluminum, or the like.

According to another embodiment of the invention, the disclosed packaging technique is compatible with various multi-package configurations. For example, the disclosed packaging technique may be used with system-in-a-package (SiP), package-on-package (PoP), and package-in-package (PiP) packaging techniques.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles, and some of the elements are enlarged and positioned to improve understanding of the inventive features

FIG. 1A is a schematic cross-sectional view of a heat sink having a recess for use as an integrated circuit package, according to an embodiment of the invention.

FIG. 1B is a top plan view of FIG. 1A, according to an embodiment of the invention.

FIG. 2 is a schematic cross-sectional view illustrating a manufacturing process used to apply an adhesive to the recess of the integrated circuit package shown in FIG. 1A, according to an embodiment of the invention.

FIG. 3 is a schematic cross-sectional view illustrating a manufacturing process used to apply a flexible substrate to the recess of the integrated circuit package shown in FIG. 2, according to an embodiment of the invention.

FIGS. 4A-4B are top plan views illustrating the application of flexible substrates to arrays of recesses of integrated circuit packages, according to an embodiment of the invention.

FIG. 5A is a schematic cross-sectional view illustrating the physical and electrical coupling of a semiconductor die to the integrated circuit package shown in FIG. 3, according to an embodiment of the invention.

FIG. 5B is a top plan view of FIG. 5A, according to an embodiment of the invention.

FIG. 6 is a schematic cross-sectional view illustrating the addition of a mold encapsulate and solder balls to the integrated circuit package shown in FIG. 5A, according to one embodiment of the invention.

FIG. 7 is a schematic cross-sectional view of a flip-chip semiconductor die positioned in a single step recess of an integrated circuit package, according to another embodiment of the invention.

FIG. 8 is a schematic cross-sectional view illustrating a manufacturing process of singulating an array of integrated circuit packages, according to an embodiment of the invention.

FIG. 9 is a schematic cross-sectional view of a wire-bonded semiconductor die in a single-step recess of an integrated circuit package, according to an embodiment of the invention.

FIG. 10 is a schematic cross-sectional view of a flip-chip semiconductor die in a multi-step recessed integrated circuit package, according to an embodiment of the invention.

FIG. 11 is a schematic cross-sectional view illustrating the addition of a heat slug over a wire-bonded semiconductor die in an integrated circuit package, according to an embodiment of the invention.

FIG. 12 is a schematic cross-sectional view illustrating an integrated circuit package which exposes a surface of a semiconductor die positioned within a recess of the integrated circuit package, according to an embodiment of the invention.

FIG. 13 is a top plan view of a ball grid array of integrated circuit package having an array of semiconductor dies, according to an embodiment of the invention.

FIG. 14 is a schematic cross-sectional view of a stacked integrated circuit package, according to an embodiment of the invention.

FIG. 15 is a schematic cross-sectional view of a stacked integrated circuit package, according to another embodiment of the invention.

FIG. 16 is a schematic cross-sectional view a stacked integrated circuit package, according to another embodiment of the invention.

### DETAILED DESCRIPTION

In the description provided herewith, certain specific details are set forth in order to provide a thorough understanding of various disclosed embodiments. However, one skilled in the relevant art will recognize that embodiments may be practiced without one or more of these specific details, or with other methods, components, etc. In some instances, well-known structures or processes associated with fabrication of MEMS have not been shown or described in detail to avoid unnecessarily obscuring descriptions of the inventive embodiments.

Unless the context requires otherwise, throughout the specification and claims that follow, the words “comprise” and “include” and variations thereof, such as “comprises,” “comprising,” and “including,” are to be construed in an open, inclusive sense, that is, as meaning “including, but not limited to.”

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in the specification and appended claims, the use of “correspond,” “corresponds,” and “corresponding” is intended to describe a ratio of or a similarity between referenced objects. The use of “correspond” or one of its forms should not be construed to mean the exact shape or size.

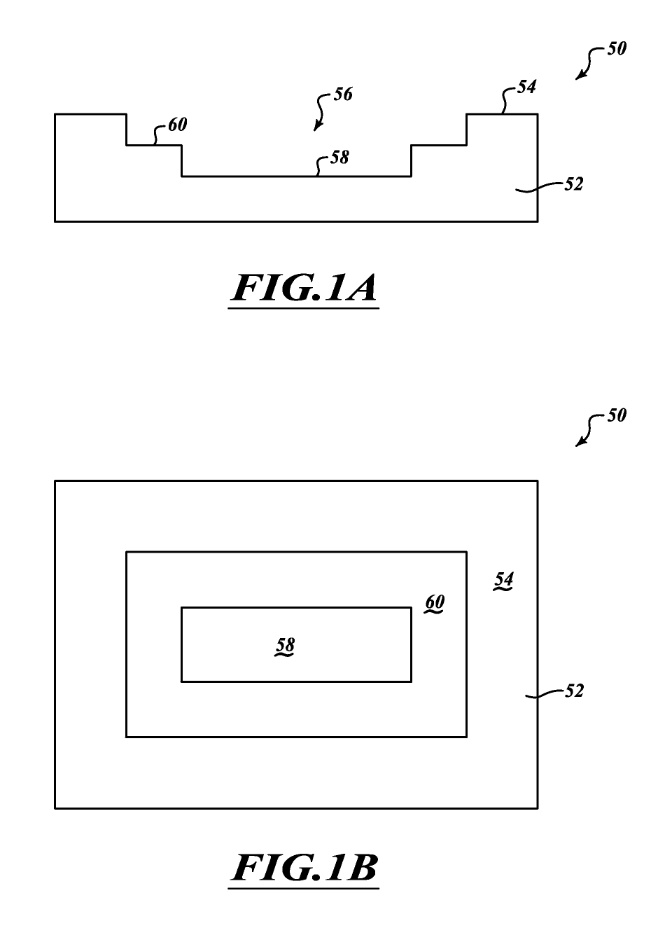

FIGS. 1-8 illustrate various stages in a method of packaging semiconductor dies in accordance with several embodiments of the invention. In the illustrated method, the semiconductor dies are packaged as part of a batch process. According to another embodiment, a single semiconductor die can be packaged according to the illustrated method.

FIG. 1A is a schematic side cross-sectional view of a recess formed in an integrated circuit (IC) package 50. The IC package 50 includes a heat sink 52 having an upper surface 54 and a recess 56 that defines a floor 58 and a raised step 60 within the heat sink 52. The heat sink 52 is also referred to in the industry as a heat spreader, radiator, fins, or other thermal transfer device, all of which are included in the meaning of heat sink as used herein.

The heat sink 52 is formed from a material having a high K value (thermal conductivity). High K values for thermally conductive material generally refer to materials having a K value of at least 10 W/(m·K), and more preferably having a k-value of at least 100 W/(m·K). For example, many plastic molding compounds are generally composite materials consisting of epoxy resins, phenolic hardeners, silicas, and mold release agents, which may combine to have a K value of 1.1-1.3 W/(m·K). By contrast many metals have a significantly higher K value than plastic molding. Specifically, pure aluminum has a K value between 204-249 W/(m·K), pure copper has a K value between 350-400, and pure silver has a K value between 406-430. According to one embodiment, the heat sink 52 is made of metal, preferably copper.

The recess 56 is shaped or formed into the heat sink 52, according to one embodiment. The heat sink 52 may be formed from sheet metal or otherwise from a block of metal. In one embodiment, portions of the heat sink 52 are milled away to form the floor 58 and the raised step 60 of the recess 56. According to one embodiment, the sidewalls of the recess 56 that surround the floor 58 and the raised step 60 are substantially perpendicular to the floor 58. In one embodiment, the recess 56 is stamped into a metal sheet to form the heat sink 52.

The heat sink 52 is molded to have the recess 56, according to another embodiment. A metal, such as copper, is heated to a liquid phase and poured into mold having a contour that is a negative of the floor 58 and the raised step 60 of the recess 56. Upon cooling, the heat sink 52 is removed from the mold for use in the additional manufacturing process steps described herein.

FIG. 1B is a plan view of the IC package 50, according to one embodiment of the invention. The upper surface 54, the floor 58, and the raised step 60 all have outer perimeters that are rectangular. According to another embodiment, the shapes of the outer perimeter of each of the upper surface 54, the floor 58, and the raised step 60, are squares, are polygons having more than 4 sides, or are henagonal.

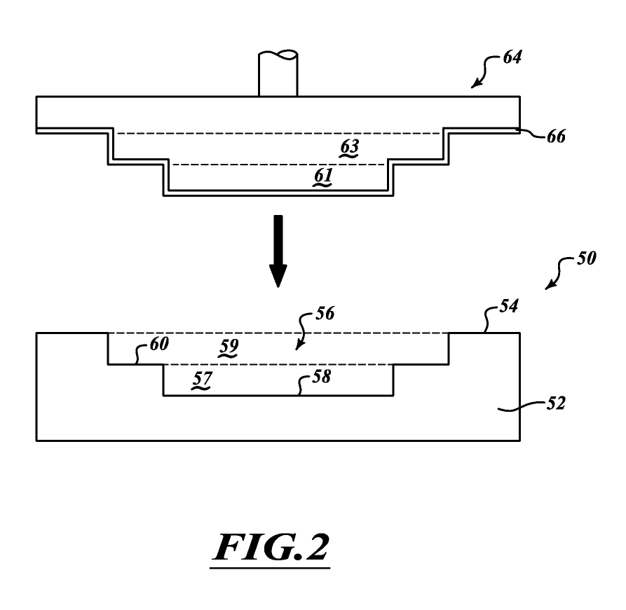

FIG. 2 illustrates a manufacturing process step of applying an adhesive to the heat sink 52 of the IC package 50, according to an embodiment of the invention. An adhesive 66 is applied to an upper peddle tool 64. The upper peddle tool 64 is shaped to contour to the inner surfaces of the recess 56 and has a first portion 61 and a second portion 63. The first portion 61 is shaped to fit into a lower portion 57 of the recess 56, and the second portion 63 is shaped to fit into an upper portion 59 of the recess 56. The upper peddle tool 64 is lowered to bring the adhesive 66 in contact with the upper surface 54, the floor 58, the raised step 60, and all of the sidewalls within the recess 56. The adhesive 66 is a thermally conductive adhesive. According to one embodiment, the adhesive has a low K value and is sprayed onto the upper surface 54, the floor 58, and the raised step 60 of the heat sink 52.

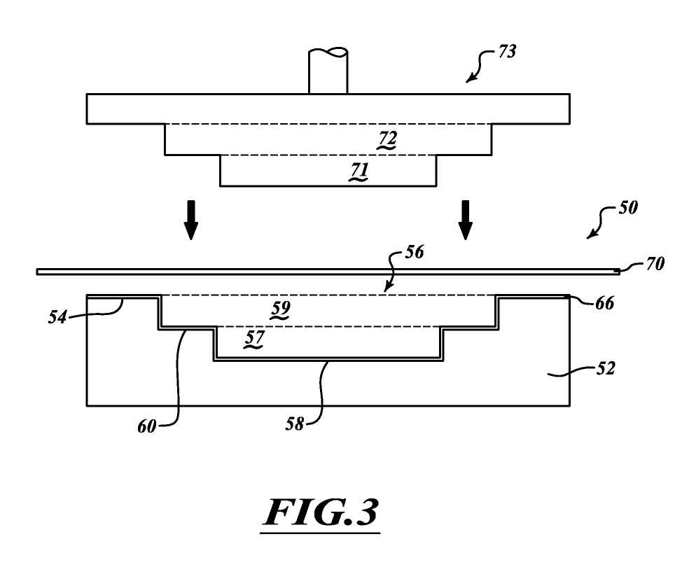

FIG. 3 illustrates a manufacturing process step of positioning a flexible substrate 70 onto the IC package 50 by using an upper peddle tool 73, according to an embodiment of the invention. The upper peddle tool 73 includes a first portion 71 and a second portion 72. The first portion 71 is shaped to fit into the lower portion 57 of the recess 56 while providing sufficient space between the first portion 71 and the lower portion 57 for the flexible substrate 70 to contour to the floor 58 and sidewalls of the recess 56. The second portion 72 is shaped to fit into the upper portion 59 of the recess 56 while providing space between second portion 72 and the upper portion 59 for the flexible substrate 70 to contour to the sidewalls of the recess 56.

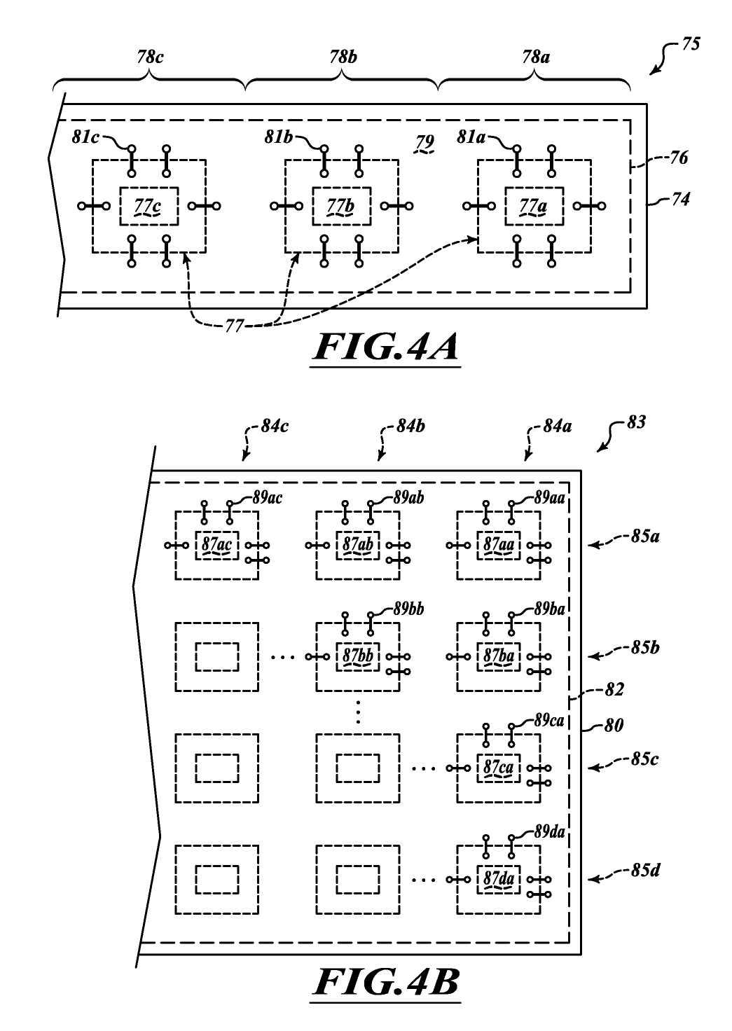

The upper peddle tool 73 presses the flexible substrate 70 onto the adhesive 66 that has been applied over portions of the heat sink 52. The flexible substrate 70 electrically isolates the metal heat sink 52 from a semiconductor die that will be positioned into the recess 56 during a subsequent process step. The electrical isolation provided by the flexible substrate 70 between the heat sink 52 and the semiconductor die advantageously enables the use of metals and other high K materials for the heat sink 52 that would otherwise interfere with and potentially short-circuit portions of the semiconductor die. The flexible substrate 70 is made from a flexible dielectric. According to one embodiment, the flexible substrate 70 includes one or more layers of polyimide. Many other types of flexible conductors are known in the art, all of which would be considered usable as equivalents here. The flexible substrate carries a plurality of electrically conductive traces (shown in FIG. 4A) embedded or bonded to the flexible substrate 70 in order to route electrical signals into and out of the semiconductor die that will be positioned inside of the recess 56. The traces will be described in more detail in connection with subsequent figures.

According to one embodiment, a flexible substrate 70 is cured into the recess 56 for some predetermined duration of time. After pressing the flexible substrate 70 into the recess 56, the IC package 50 is placed within an environment having a temperature in the range of 150° C. to 250° C. for at least 30 min. More preferably, the IC package is placed within the environment having a temperature in the range of 150° C. to 250° C. for at least two hours to cure the flexible substrate 70 into the recess 56. According to another embodiment, the IC package 50 is placed into an environment having a temperature in the range of 150° C. to 250° C. for at least 30 minutes and less than one hour after pressing the flexible substrate 70 into the recess 56.

The use of the flexible substrate 70 to route signals from to and from a semiconductor die positioned in the recess 56 has several advantages over the existing techniques used for packaging semiconductor dies. For example, as will be shown below, a semiconductor die positioned within the recess 56 may be physically and electrically coupled to the flexible substrate 70 using conductive bumps that are located on one side of the semiconductor die or the semiconductor die may physically and electrically coupled to the flexible substrate 70 via wire bonds. The flexible substrate 70 also enables communicative access to the semiconductor die without forming perforations through the heat sink 52 and without needing to expose an upper surface of the semiconductor die in order to form electrical connections to bonding pads of the die by forming openings in a masking layer and depositing metal therein. Advantageously, by relying on traces carried by the flexible substrate 70 rather than forming electrical connections to the semiconductor die through perforations in the heat sink 52, the heat sink 52 may be formed from a high K value material, such as metal, without grounding or substantially interfering with the electrical connections made to the semiconductor die.

FIG. 4A illustrates a manufacturing process of applying a flexible substrate 74 to a one-dimensional array of IC packages 75, according to an embodiment of the invention. The flexible substrate 74 is positioned over a heat sink 76 having a plurality of recesses 77a-c (cumulatively referred to as 77). The perimeter dimensions of the flexible substrate 74 are greater than the perimeter dimensions of the heat sink 76 so that the flexible substrate 74 continues to cover an upper surface 79 of the heat sink 76 after the flexible substrate 74 has been conformally pressed or molded into the plurality of recesses 77. According to one embodiment, heat is applied to the flexible substrate 74 to increase the pliability of the flexible substrate 74 prior to applying the flexible substrate 74 to the heat sink 76. According to another embodiment, a portion of the flexible substrate 74 that is associated with each IC package 78a-c, is pressed into respective recesses 77a-c one recess at a time. As illustrated, the flexible substrate 74 also carries a plurality of sets of traces 81a-c (cumulatively referred to as 81).

The sets of traces 81 that are carried by the flexible substrate 74 are low-resistance electrical conductors made from metal. The traces 81 are attached to the flexible substrate 74 prior to conforming the flexible substrate 74 into the recesses 77. The traces 81 are attached to the surface of the flexible substrate 74 with an adhesive. According to one embodiment, the flexible substrate 74 comprises multiple layers of material, and the traces 81 are bonded to the flexible substrate 74 prior to the addition of a last layer so that a portion of the last layer of the flexible substrate 74 is removed to expose the traces 81. According to another embodiment, metal is liquefied and poured into small openings or molds in the flexible substrate 74 to form the sets of traces 81. The traces 81 are made thin enough to flexibly conform to the recesses 77 while the flexible substrate 74 is pressed into the recesses 77, and the traces are thick enough to withstand the friction applied to the surface of the traces 81 while the flexible substrate 74 is pressed into the plurality of recesses 77. According to one embodiment, the thickness of the traces 81 is greater than or equal to approximately 20 μm and less than or equal to approximately 200 μm.

Although not illustrated, each of the sets of traces 81a-c will be offset from the center of each of the respective recesses 77a-c so that each of the traces 81a-c will a line with their respective recesses 77a-c as one or more portions of the flexible substrate 74 is pressed into one or more of the recesses 77.

In a later manufacturing process step, each of the IC packages 78a-c of the one dimensional array of IC pages 75 may be singulated by one of several techniques that will be discussed below.

FIG. 4B illustrates a manufacturing process of applying a flexible substrate 80 to a two-dimensional array of IC packages 83, according to an embodiment of the invention. The flexible substrate 80 is positioned over a heat sink 82 having a plurality of recesses 87aa-87dc (cumulatively referred to as 87). The flexible substrate 80 carries a plurality of sets of traces 89. The perimeter dimensions of the flexible substrate 80 are greater than the perimeter dimensions of the heat sink 82 to compensate for the area of the flexible substrate 80 that will be pressed into the recesses 87. According to one embodiment, a portion of the flexible substrate 80 is pressed into the recesses 87 beginning from a corner recess 87aa and followed by the recesses 87ba-87da of column 84a. The flexible substrate 80 is then pressed into the recesses 87 of the columns 84b and 84c, one column at a time. In another embodiment, the flexible substrate 80 is pressed into each of the recess 87 of rows 85a, 85b, 85c, 85d, one row at a time. While FIG. 4B illustrates 4 rows and 3 columns of recesses 87, 5's, 10's, or 100's of rows and columns of recesses 87 may be formed into the heat sink 82, according to one embodiment.

To facilitate understanding of the embodiment illustrated in FIG. 4B, each of the sets of traces 89 has been aligned with their respective recesses 87. However, in practice the traces 89 will not all align with their respective recesses 87 prior to the traces 89 being pressed into their respective recesses 87. To the contrary, many of the sets of traces 89 will initially be offset from their respective recesses 87 in accordance with the sequence established for pressing portions of the flexible substrate 80 into the recesses 87.

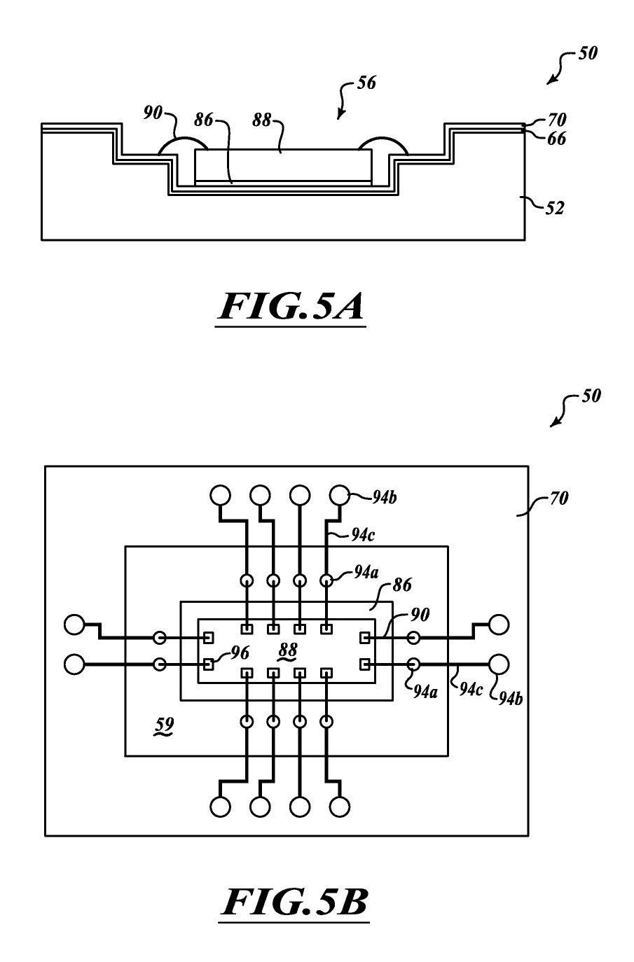

FIG. 5A is a schematic side cross-sectional view of a semiconductor die 88 that has been physically and electrically coupled to the flexible substrate 70 of the IC package 50, according to one embodiment of the invention. The semiconductor die generally has an integrated circuit, a micro-electromechanical system (MEMS), or/and a plurality of bond pads coupled to the integrated circuit. The bond pads are reinforced sections of conductive material positioned on a surface of the semiconductor die 88 to facilitate electrical connection to the semiconductor die 88 via conductive bumps, solder balls, or wire-bonding.

Adhesive 86 physically couples the semiconductor die 88 to the flexible substrate 70, according to one embodiment of the invention. The adhesive 86 is a die paste that is applied to the bottom of the semiconductor die 88 prior to positioning the semiconductor die 88 into the recess 56. The adhesive 86 secures the semiconductor die 88 in place during the subsequent wire-bonding and mold encapsulation process steps. Alternatively, the adhesive 86 is sprayed or squirted into the bottom of the recess 56 prior to positioning semiconductor die 88 into the recess 56.

Wire bonds 90 electrically couple or connect the semiconductor die 88 to the flexible substrate 70, according to one embodiment of the invention. Wire bonds 90 are attached to bonding pads located on the semiconductor die 88 and are arcuately attached to corresponding pads of the conductive traces that are attached to the flexible substrate 70. Wire-bonding is the most traditional and cheapest technology used for forming electrical connections to a semiconductor die. According to one embodiment, the wire diameter of the wire bonds 90 is greater than or equal to 15 μm and less than or equal to 50 μm. The wire bonds 90 are formed from gold, aluminum, or copper, according to various embodiments of the invention.

FIG. 5B is a plan view of IC package 50 and illustrates the physical and electrical coupling of the semiconductor die 88 to traces 94, according to an embodiment of the invention. Each trace 94 includes a first trace pad 94a, a second trace pad 94b and a trace pad interconnection member 94c that connects each respective first trace pad 94a to each respective second trace pad 94b. The bonding wires 90 are arcuately attached from the plurality of bonding pads 96 to each of the respective first trace pads 94a which are positioned over the raised step 60. The raised step 60 bifurcates the recess 56 so that the semiconductor die 88 is positioned into a lower portion 57 of the recess 56, and the bonding wires 90 are connected to the trace pads 94a in an upper portion 59 of the recess 56 (upper portion 59 and lower portion 57 are illustrated in FIGS. 2-3). The second trace pad 94b is positioned over the upper surface 54 of the heat sink 52 to facilitate solder ball attachment or electrical interface with other devices or components.

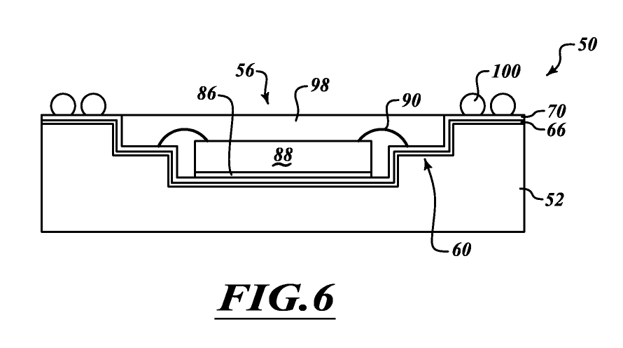

FIG. 6 illustrates a manufacturing process of adding a mold encapsulant 98 and a plurality of solder balls 100 to the IC package 50, according to one embodiment of the invention. The mold encapsulant 98 fills the recess 56 and solidifies the positions of both the semiconductor die 88 and the bonding wires 90. The mold encapsulant 98 concurrently provides protection to the bonding wires 90 from inadvertent damage.

The mold encapsulant 98 is an electrical insulator that electrically isolates the bonding wires 90 from each other, according to one embodiment. The mold encapsulant 98 consists of plastic or epoxy. The mold encapsulant 98 is heated to a liquid state and is injected into the recess 56 of the IC package 50. After cooling, the mold encapsulant 98 is chemically or mechanically planed to a flat surface, according to one embodiment.

Solder balls 100 are attached to the second trace pads 94b after the application of the mold encapsulant 98. The solder balls 100 are fully spherical or are solder bumps that are not fully spherical. The solder balls 100 are made from tin, tin-zinc, tin-copper, tin-bismuth, tin-silver, tin-indium, or the like. The solder balls 100 are heated and used to electrically and mechanically couple the IC package 50 to a circuit board, another IC package, a flip chip, other electronics interface.

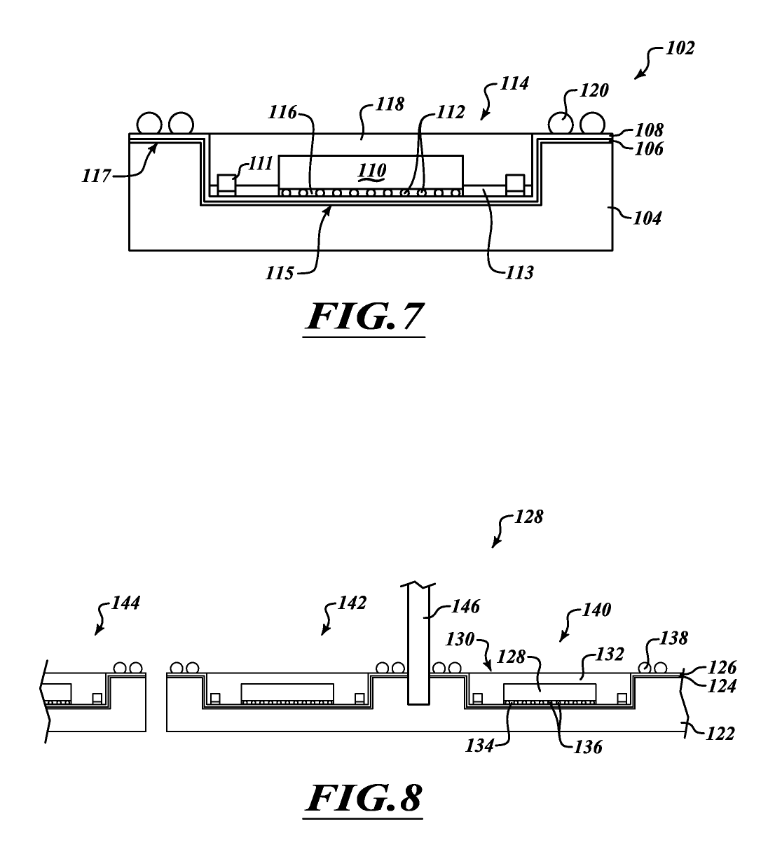

FIG. 7 illustrates an IC package 102 that is useful for packaging a flip-chip semiconductor die 110, according to one embodiment of the invention. The IC package 102 is formed using the process steps illustrated in FIGS. 1-3 and 5-6 to manufacture the IC package 50. The IC package 102 includes a heat sink 104, a flexible substrate 108 positioned within a single-step recess 114 of the heat sink 104, the semiconductor die 110, and solder balls 120.

The heat spreader or heat sink 104 is formed from a sheet or block of metal having a high K value. As discussed above in connection with other embodiments, a high K value is a thermal conductivity that is at least 10 W/(m·K). More preferably, the high K value is a thermal conductivity that is at least 100 W/(m·K). Accordingly, the heat sink 104 may be formed from a sheet or block of copper, aluminum, brass, or other metal.

A recess 114 is formed or machined into the heat sink 104 to receive the semiconductor die 110. As discussed above, according to another embodiment, liquid metal is poured into a mold to form the recess 114 and heat sink 104 into the particular shape illustrated in FIG. 7. Alternatively, the recess 114 is machined from the heat sink 104 with a mill, or the recess 114 is stamped into the heat sink 104. The recess 114 defines a floor region 115 in the heat sink 104. The floor region 115 may have a henagonal or polygonal shape, according to several embodiments of the invention.

A flexible substrate 108 is conformally positioned over the heat sink 104 and into the recess 114. The flexible substrate 108 is pressed into the recess 114 using a tool that is shaped to fit inside the recess 114 to apply pressure to the flexible substrate 108, causing the flexible substrate 108 to conform to the shape of the recess 114. Additionally, the flexible substrate 108 is heated to facilitate the manufacturing process step of conformally pressing the flexible substrate 108 into the recess 114, according to one embodiment. The flexible substrate 108 is adhered to the heat sink 104 using an adhesive 106. The flexible substrate 108 electrically separates the semiconductor die 110 from the heat sink 104 while permitting heat generated from the semiconductor die 110 to pass to the heat sink 104 through thermal conduction so the heat sink 104 may further transfer the heat via radiation to other thermal systems. The flexible substrate 108 is formed from polyimide, according to one embodiment of the invention.

Various electrical components may be attached to the flexible substrate 108 inside the recess 114. For example, the flip-chip semiconductor die 110 having a ball grid array (BGA) 112 is connected to traces carried by the flexible substrate 108. In place of bonding wires, the BGA 112 provides both electrical and mechanical coupling or connection to the flexible substrate 108. The BGA 112 are bumps of solder, gold, or copper, according to various embodiments of the invention. Advantageously, a small bump of metal is smaller and shorter than a long wire and therefore can conduct a signal much faster and at a higher bandwidth than a bond wire. Passive components 111, such as capacitors, are also connected to traces carried by the flexible substrate 108 to condition the signals passing through the traces, according to one embodiment.

A layer of thermal fill 113 is deposited over the floor region 115 of the flexible substrate 108 to fill the spaces between the bottom surface of the semiconductor die 110, the BGA 112, and the flexible substrate 108. The layer of thermal fill 113 is deposited prior to filling the recess 114 with a mold encapsulant 118. Transferring heat via radiation through air is less thermally-efficient than transferring heat via conduction. Therefore, depositing a thermal fill 113 between the bottom surface of the semiconductor die 110, the BGA 112, and the flexible substrate 108 facilitates the conductive transfer of heat from the semiconductor die 110 to the heat sink 104 whereby the heat is radiated and/or further conducted to additional heat sinks.

A mold encapsulant 118 is injected or deposited to fill the recess 114. The mold encapsulant 118 secures in place the flip-chip semiconductor die 110 and the plurality of passive components 111.

Solder balls 120 are deposited on trace pads located above an upper surface 117 of the heat sink 104. The solder balls 120 enable the IC package 102 to be both electrically and mechanically coupled to other IC packages, circuit boards, or other electronic devices.

FIG. 8 illustrates a manufacturing process of singulating an array of IC packages 128, according to an embodiment of the invention. The array of IC packages 128 includes a first IC package 140, a second IC package 142, and a third IC package 144. As illustrated in the third IC package 144 has already been singulated from the remaining IC packages of the array of IC packages 128.

As described above, the first IC package 140 includes a flexible substrate 126 conformally adhered to a heat sink 122, and a semiconductor die 128 positioned within a recess 130 that has been formed or shaped into the heat sink 122, according to one embodiment. The semiconductor die 128 is electrically and mechanically coupled or connected to traces carried on the flexible substrate 126 with a BGA 136. Alternatively, the semiconductor die 128 is electrically and mechanically coupled or connected to traces carried on the flexible substrate 126 with bonding wires. A mold encapsulant 132 is deposited over the semiconductor die 128 to fill the recess 130 and enclose the semiconductor die 128.

A saw blade 146 singulates the array of IC packages 128 into individual IC packages 140, 142, and 144, according to one embodiment. At thousands of revolutions per minute, the saw blade 146 cuts between solder balls 138 of each of the IC packages 140, 142, and 144. According to another embodiment, a laser is used to cut between IC packages 140, 142, and 144.

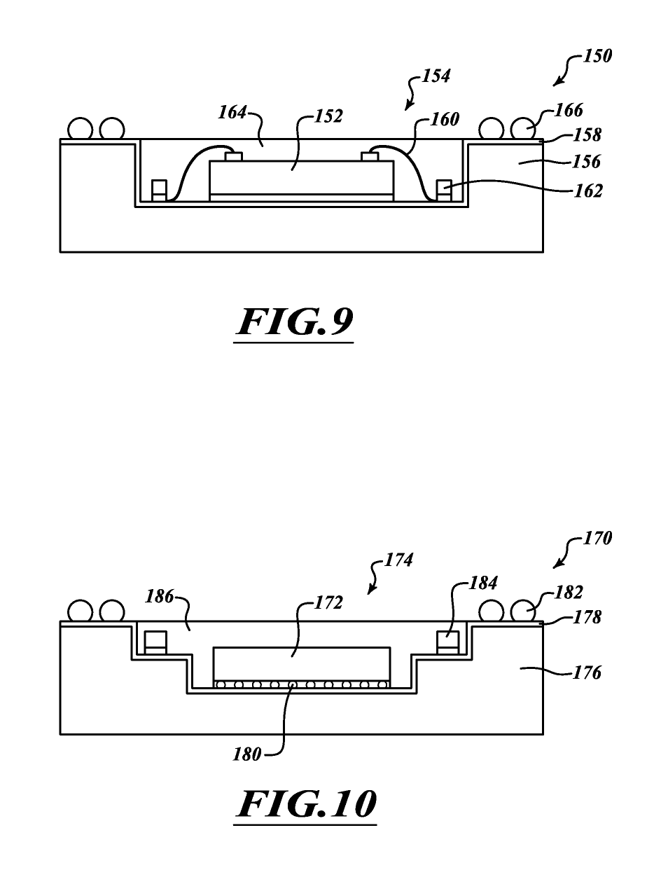

FIG. 9 is a schematic side cross-sectional view illustrating a wire-bonded semiconductor die in a single-step recess of an IC package 150, according to an embodiment of the invention. The IC package 150 includes a semiconductor die 152 positioned in a recess 154 of a heat sink 156. The semiconductor die 152 is electrically connected to traces on a flexible substrate 158 via bonding wires 160. Passive components 162 are also electrically connected to one or more of the traces within the recess 154, according to one embodiment. The semiconductor die 152, the passive components 162, and the bonding wires 160 are secured in place using a mold encapsulant 164, according to one embodiment of the invention. Solder balls 166 provide external electrical connections to the bonding wires 160 and the semiconductor die 152.

FIG. 10 is a schematic side cross-sectional view illustrating a flip-chip semiconductor die in a multi-step recessed IC package 170, according to an embodiment of the invention. The IC package 170 includes a flip-chip 172 positioned in a multi-step recess 174 of a heat sink 176. The semiconductor die 172 is electrically connected to traces on a flexible substrate 178 via a plurality of conductive bumps or solder balls 180. Solder balls 182 provide external electrical connection to the plurality of solder balls 180 that are attached to semiconductor die 172. According to one embodiment, the plurality of passive components 184, such as capacitors, are also electrically connected to one or more traces on the flexible substrate 178 in between the solder balls 180 and the solder balls 182. A mold encapsulant 186 is deposited to fill the recess 174 and secure the semiconductor die 172 and the passive components 184 in place.

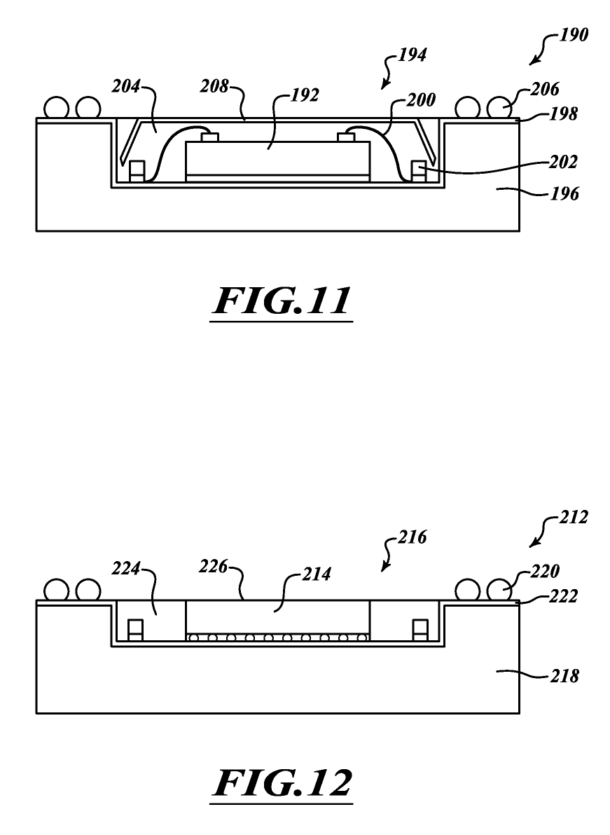

FIG. 11 is a schematic side cross-sectional view illustrating the addition of a heat slug over a portion of a semiconductor die positioned within the recess 194 of an IC package 190, according to an embodiment of the invention. The IC package 190 includes the semiconductor die 192 positioned in the recess 194 of a heat sink 196. The semiconductor die 192 is electrically connected to traces on a flexible substrate 198 via bonding wires 200. Passive components 202 are also positioned within the recess 194 and connected to the traces carried by the flexible substrate 198, according to one embodiment. The semiconductor die 192 and the bonding wires 200 are secured in place by a mold encapsulant 204, according to one embodiment of the invention. Solder balls 206 provide external electrical connection to the bonding wires 200 and the semiconductor die 192. Additionally, IC package 190 includes a heat slug 208 that is positioned over the semiconductor die 192 and bonding wires 200 to provide an additional structure to conduct and radiate heat transferred from the semiconductor die 192. The heat slug 208 may be formed from lead, copper, aluminum, or another metal, and may be deposited as an intermediate step of filling the recess 194 with mold encapsulant 204. According to one embodiment, the heat slug 208 is further coupled to another heat sink such as a thermal radiator having a plurality of fins configured to radiate the conducted heat.

FIG. 12 is a schematic side cross-sectional view illustrating an IC package 212 which exposes a surface of a semiconductor die, according to an embodiment of the invention. Similar to previously disclosed embodiments, the IC package 212 includes a semiconductor die 214 positioned within a single step recess 216 that has been formed within a heat sink 218. The semiconductor die 214 is electrically connected to a plurality of solder balls 220 through traces (as shown in FIGS. 4A, 4B, and 5B) located on a conformal layer 222. According to one embodiment, in order to increase the dissipation of heat from the semiconductor die 214, a mold encapsulant 224 is deposited within the recess 216 and later mechanically or chemically planed to expose a surface 226 of the semiconductor die 214 to enhance the radiation of heat from the semiconductor die 214. A heat sink (not shown in this Figure) is then coupled to the exposed surface 226 of the semiconductor die 214 in order to facilitate the radiation of heat conducted away from the semiconductor die 214.

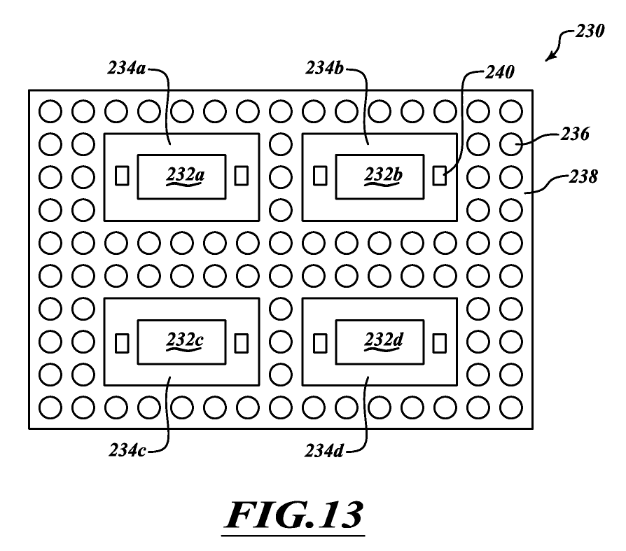

FIG. 13 is a top-view diagram illustrating a ball grid array (BGA) package 230 having a plurality of semiconductor dies 232a-d arranged in a 2×2 array, according to an embodiment of the invention. The BGA package 230 includes semiconductor dies 232a-d positioned in recesses 234a-d, respectively. Each of the semiconductor dies 232a-d are electrically connected to the plurality of solder balls 236 via traces (as shown in FIGS. 4A, 4B, and 5B) carried by the flexible substrate 238. A plurality of passive components 240, such as capacitors, are also carried by the conformal layer 238 within the recesses 234a-d and are electrically connected to the semiconductor dies 232a-d. As illustrated, the semiconductor dies 232a-d are flip-chip dies relying on solder balls to connect the individual dies to the flexible substrate 238 within each of the respective recesses 234a-d. According to another embodiment, the semiconductor dies 232a-d are coupled to the flexible substrate 238 within the recesses 234a-d via wire bonding, as illustrated in previous embodiments. As illustrated, the array of semiconductor dies is two dies long and two dies wide. According to another embodiment, the BGA package 230 includes greater or less dies per each row and each column.

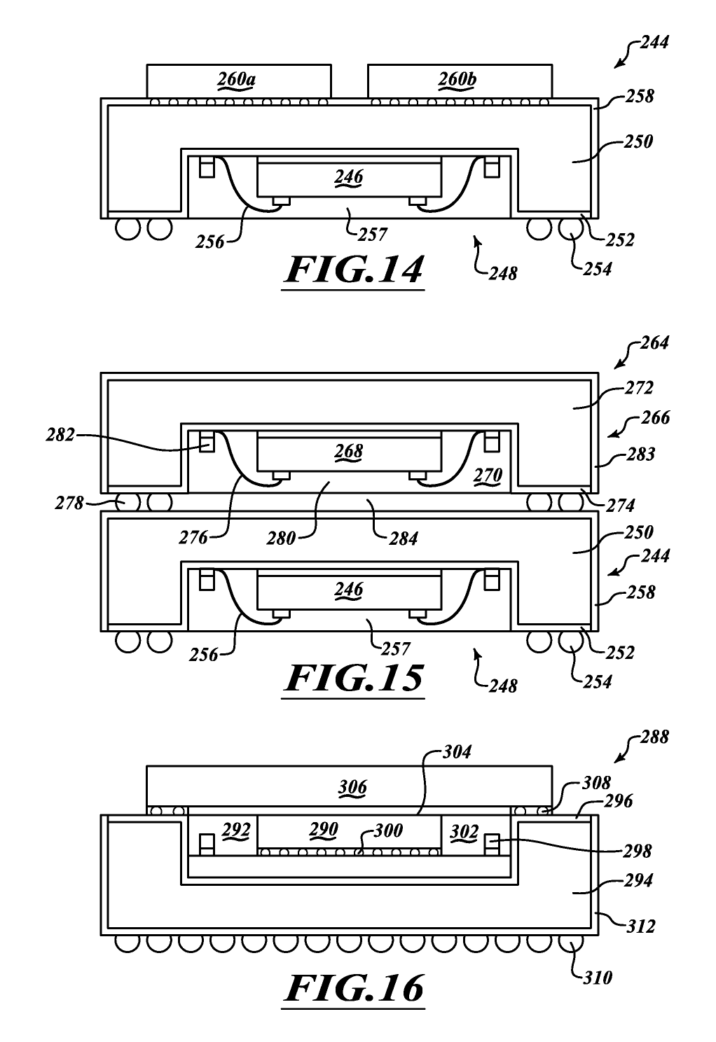

FIG. 14 is a schematic side cross-sectional view illustrating a flip-chip stacked IC package 244, according to an embodiment of the invention. The IC package 244 includes a semiconductor die 246 positioned within a recess 248 of a heat sink 250 that is configured to remove and dissipate heat from the semiconductor die 246. Similar to previous embodiments, the semiconductor die 246 is electrically connected to a flexible substrate 252 that has been pressed into the recess 248 and that carries a plurality of traces (as shown in FIGS. 4A, 4B, and 5B). A plurality of solder balls 254 provide an external electrical connection to the semiconductor die 246 and are coupled to the semiconductor die 246 through a plurality of bonding wires 256. The semiconductor die 246 and the plurality of bonding wires 256 are secured in place within the recess 248 by filling the recess 248 with a mold encapsulant 257.

The IC package 244 also includes a flexible substrate 258 that is configured to conform around a plurality of external surfaces of the heat sink 250. The flexible substrate 258 includes a plurality of traces (as shown in FIGS. 4A, 4B, and 5B). The traces couple a first flip-chip semiconductor die 260a and a second flip-chip semiconductor die 260b to the plurality of solder balls 254 and to the semiconductor die 246. The flip-chip semiconductor dies 260a, 260b are also communicatively coupled to each other through the plurality of traces, according to one embodiment. According to another embodiment, the semiconductor die 246 may be electrically coupled to the flexible substrate 252 via a plurality of solder balls instead of via the bonding wires 256.

The semiconductor dies 260a and 260b are devices that function in conjunction with the semiconductor die 246 to perform a specific function, according to one embodiment. For example, the semiconductor die 246 may include a controller integrated circuit for a DC-DC buck converter, and each of the semiconductor dies 260a and 260b are phase controlling devices that work in a master-slave relationship with the semiconductor die 246. As another example, the semiconductor die 246 may be a processor, semiconductor dies 260a and 260b are memory devices, and the semiconductor die 246 is configured to store and retrieve information from memory devices.

According to one embodiment, the semiconductor die 246 includes a plurality of smaller semiconductor dies in a package-in-package configuration. According to another embodiment, the semiconductor die 246 includes a plurality of diverse components in a system-in-a-package configuration.

FIG. 15 is a schematic side cross-sectional view illustrating a package-on-package (PoP) IC package 264, according to another embodiment of the invention. The PoP IC package 264 includes IC package 244 and IC package 266. Similar to the IC package 244, the IC package 266 also includes a semiconductor die 268 positioned within a recess 270 of a heat sink 272. The semiconductor die 268 is electrically connected to a flexible substrate 274 that is pressed into the recess 270. A plurality of bonding wires 276 electrically connect the semiconductor die 268 to a plurality of solder balls 278, and a mold encapsulant 280 fills the recess 270 two secure the semiconductor die 268, the bonding wires 276, and a plurality of passive devices 282 that are within the recess 270. The IC package 266 may also include a flexible substrate 283 that carries a plurality of traces (as shown in FIGS. 4A, 4B, and 5B) configured to electrically couple the plurality of solder balls 278 and the semiconductor die 268 to one or more additional electronic devices.

In the PoP IC package 264, the IC package 266 is electrically and physically coupled to the IC package 244, according to one embodiment of the invention. The solder balls 278 of the IC package 266 are adhered to traces carried by the flexible substrate 258 of the IC package 244. The solder balls 278 are heated to liquefy the solder balls 278 so that they adhere to traces carried by the conformal layer 258. Through the electrical and physical connection of the solder balls 278 to the traces carried by the flexible substrate 258, the semiconductor die 268 is communicatively coupled to the semiconductor die 246 and/or to the solder balls 254. According to one embodiment, additional IC packages similar to IC package 244 and IC package 266 may also be electrically and physically coupled to the PoP IC package 264.

According to one embodiment the semiconductor die 246 and the semiconductor die 268 perform similar functions, that is, they are similar devices. According to another embodiment, the semiconductor die 246 and semiconductor die 268 are different types of devices and perform functions that support the operation of each other.

According to another embodiment, a gap 284 that is between the IC package 244 and IC package 266 may be filled with a high K dielectric that thermally couples the IC packages together to improve the ability of the stacked IC package 264 to dissipate heat from each of the semiconductor dies to 246 and 268.

As illustrated, the IC packages 244 and 266 include wire-bonded semiconductor dies 246 and 268 positioned within single step recesses 248 and 270, respectively. According to other embodiments, one or more of the IC packages that constitute the PoP IC package 264 are flip-chip semiconductor dies positioned within single step or multi-step recesses within IC packages.

FIG. 16 is a schematic side cross-sectional view illustrating another PoP IC package 288, according to another embodiment of the invention. The PoP IC package 288 includes a flip-chip semiconductor die 290 positioned within a recess 292 of the heat sink 294. The semiconductor die 290 is electrically connected to a plentiful substrate 296 and a plurality of passive devices 298 via a plurality of solder balls 300 and a plurality of traces (as shown in FIGS. 4A, 4B, and 5B) carried by the flexible substrate 296. The semiconductor die 290 and the plurality of passive components 298 are secured in place by filling the recess 292 with a mold encapsulant 302. The mold encapsulant 302 is mechanically or chemically planed after deposition to expose an upper surface 304 of the semiconductor die 290.

The PoP IC package 288 includes a flip-chip semiconductor die 306 that is electrically and mechanically coupled to the conformal layer 296 via a plurality of solder balls 308. The electrical connection of the semiconductor die 306 to the conformal layer 296 via the solder balls 308 communicatively couples the semiconductor die 306 to the semiconductor die 290, according to one embodiment. Both the semiconductor die 290 and the semiconductor die 306 are electrically connected to a plurality of solder balls 310 that are electrically and physically coupled to traces (as shown in FIGS. 4A, 4B, and 5B) carried by a flexible substrate 312. According to one embodiment, the flexible substrate 296 electrically connects a portion of the plurality of solder balls 302 to a respective portion of the plurality of solder balls 308 and the electrical connections provided by the respective portions are not made available to the plurality of solder balls 310. Thus, some of the communication signals between the semiconductor die 290 and the semiconductor die 306 are hidden and made inaccessible to probing and analysis at the externally available solder balls 310. Such a feature may be useful for increasing the difficulty of reverse engineering the interface between the semiconductor dies of the PoP IC package 288.

The above description of illustrated embodiments, including what is described in the Abstract, is not intended to be exhaustive or to limit the embodiments to the precise forms disclosed. Although specific embodiments and examples are described herein for illustrative purposes, various equivalent modifications can be made without departing from the spirit and scope of the disclosure, as will be recognized by those skilled in the relevant art.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

1. A semiconductor die package, comprising:
a metal member having a first surface;
a recess in the metal member having a substantially planar floor, the floor being parallel to the first surface and not coplanar to the first surface;
an adhesive positioned over the floor of the recess;
an insulating layer positioned over and conformed to both the first surface of the metal member and the adhesive in the recess;
a plurality of traces positioned on the insulating layer and extending from inside the recess to a portion of the insulating layer that is over the first surface;
a semiconductor die positioned over the floor in the recess;
a plurality of electrical couplings between the semiconductor die and the plurality of traces; and
an encapsulating layer disposed over the semiconductor die.

2. The package of claim 1 wherein the insulating layer is polyimide.

3. The package of claim 1 wherein the insulating layer is approximately 12 microns thick.

4. The package of claim 1 wherein the floor of the recess is rectangular.

5. The package of claim 1 wherein the electrical couplings are wire bonding.

6. The package of claim 1 wherein the electrical couplings are a ball grid array.

7. The package of claim 1 wherein the recess includes the floor and a second planar surface that is parallel to the floor and not coplanar to the floor.

8. The package of claim 7 wherein the electrical couplings are attached to the traces over the second planar surface of the recess.

9. The package of claim 1 wherein the metal member is a portion of a sheet of metal.

10. A method, comprising:
forming a recess in a metal member, the recess having a substantially planar floor and a step region adjacent to and above the floor;
applying an adhesive to the floor of the recess;
positioning an electrically insulating conformal layer over the metal member;
pressing the electrically insulating conformal layer onto the planar floor of the recess over the adhesive;
positioning a plurality of conductive traces on the first surface of the electrically insulating conformal layer;
positioning an electronic semiconductor die in the recess over a portion of the first surface of the electrically insulating conformal layer;
coupling the electronic semiconductor die to some of the plurality of conductive traces;
forming a plurality of conductive structures over respective ones of the plurality of traces outside of the recess; and
filling the recess to encapsulate the electronic semiconductor die and a portion of some of the plurality of traces in the recess.

11. The method of claim 10 wherein the electrically insulating conformal layer is pressed into the recess with a plunger having a contour that substantially mates with a contour of the recess.

12. The method of claim 10 wherein positioning the electrically insulating conformal layer includes curing the electrically insulating conformal layer at a temperature in the range of 150° C. to 200° C. for at least 2 hours after pressing the electrically insulating conformal layer onto the planar floor.

13. The method of claim 10 wherein positioning the electrically insulating conformal layer includes curing the electrically insulating conformal layer at a temperature in the range of 150° C. to 200° C. for at least 30 minutes and less than 1 hour after pressing the electrically insulating conformal layer onto the planar floor.

14. The method of claim 10 wherein applying the adhesive includes applying the adhesive to a surface of a plunger having a contour that substantially mates with a contour of the recess and pressing the plunger into the recess.

15. The method of claim 10 wherein positioning the electronic semiconductor die into the recess includes positioning a plurality of electronic semiconductor dies into the recess.

16. A method, comprising:
forming a recessed die pad in a sheet of metal, the recessed die pad having a non-recessed region and a substantially planar recessed region;
positioning a flexible layer onto the recessed die pad so that the flexible layer contours to the non-recessed region and the recessed region, the flexible layer having a plurality of traces that extend from the non-recessed region to the recessed region, each of the plurality of traces being electrically insulated from each other respective trace by the flexible layer, at least some of the plurality of traces being electrically insulated from the recessed die pad by the flexible layer;
adhering the flexible layer to the recessed die pad with a thermally conductive adhesive;
positioning a semiconductor die in the recessed region;
electrically coupling the semiconductor die to a portion of some of the plurality of traces that are within the recessed region; and
encapsulating the semiconductor die and the portion of some of the plurality of traces that are within the recessed region.

17. The method of claim 16, further comprising:
positioning a second flexible layer to an opposite side of the recessed region;
attaching the second flexible layer to the opposite of the recessed region with the thermally conductive adhesive; and
electrically coupling a second semiconductor die to a plurality of traces carried by the second flexible layer.

18. The method of claim 16 wherein the recessed die pad is formed by displacing the recessed region of the sheet of metal with a press.

19. The method of claim 18, further comprising singulating the recessed die pad from a plurality of recessed die pads formed on the sheet of metal.
